(19) United States
(12) Patent Application Publication
(10) Pub. No.: US 2019/0074805 A1
(43) Pub. Date: Mar. 7, 2019

(54) Transient Detection for Speaker Distortion Reduction

(71) Applicant: Cirrus Logic International Semiconductor Ltd., Edinburgh (GB)

(72) Inventors: Ziad Hatab, Austin, TX (US); Eric Lindemann, Boulder, CO (US); John Melanson, Austin, TX (US)

(73) Assignee: Cirrus Logic International Semiconductor Ltd., Edinburgh (GB)

(21) Appl. No.: 15/698,193

(22) Filed: Sep. 7, 2017

(51) Int. Cl. H03G 1/04; H04R 3/00

(52) U.S. Cl. CPC H03G 1/04; H04S 2400/13; H04S 2400/09; H04R 3/002

(57) ABSTRACT

Audio distortion by a speaker may be reduced by detecting onset audio events within an audio signal and modifying the audio to reduce the audio distortion perceived by a listener. The onsets may be detected using a psych-acoustic model by determining critical sub-band powers and corresponding masking thresholds. When a loudness value calculated from the CSBs and masking thresholds exceeds a threshold level, certain frequency bands may be attenuated and other frequency bands may be amplified. The audio modification may be performed on a frame-by-frame basis and each frame may be processed multiple times until the onset is sufficiently masked or attenuated.

### CROSS-REFERENCE TO RELATED PATENT APPLICATIONS

This application is related by subject matter to U.S. patent application Ser. No. 15/698,142 entitled “Speaker Distortion Reduction” and filed on Sep. 7, 2017, which is incorporated by reference.

### FIELD OF THE DISCLOSURE

The instant disclosure relates to audio processing. More specifically, portions of this disclosure relate to audio processing to compensate for speaker distortion.

### BACKGROUND

Speakers are not capable of perfectly replicating sounds encoded in audio files. Trade-offs are made during speaker design and manufacturing to fit particular applications. For example, cost constraints may result in selection of materials for speakers that are not ideal. As another example, space constraints may result in construction of a speaker with a size that is not ideal for reproduction of all frequencies of sounds. Smaller speakers, such as those used in mobile phones, are generally less accurate with reproduction of sounds and can introduce distortion into the reproduced sounds. Furthermore, manufacturing imperfections in smaller speakers can introduce additional distortion into the reproduced sounds.

Shortcomings mentioned here are only representative and are included simply to highlight that a need exists for improved electrical components, particularly for speakers employed in consumer-level devices, such as mobile phones. Embodiments described herein address certain shortcomings but not necessarily each and every one described here or known in the art. Furthermore, embodiments described herein may present other benefits than, and be used in other applications than, those of the shortcomings described above.

### SUMMARY

Distortions introduced by a speaker may be reduced by processing an audio signal to modify the audio content and outputting the modified audio signal to the speaker for reproduction. Problematic sounds in the audio signal may be modified to reduce the impact of speaker distortion on the reproduced sounds. One problematic sound is a sound with a strong onset, which creates a rapid change in the characteristics of the sounds. The problem is worsened when the onset is near a speaker's resonant frequency or the audio signal has a spectral tilt with more energy located in lower frequencies near the speaker's resonant frequency as compared to energy located in higher frequencies. Microspeakers, or any speaker in a vulnerable state, may produce audio distortion in response to transient events, such as piano and non-piano onsets, characterized by a noticeable change in intensity, pitch, or timbre.

Audio processing may detect transient acoustic conditions conducive to distortions, such as in piano and piano-like sounds, by monitoring the audio content and compensating when the transient acoustic conditions may otherwise cause speaker distortion. The compensation may include attenuating piano and piano-like onset acoustic events before output to the speaker. Thus, sounds that are likely to cause perceived distortion are reduced. If the attenuated audio signal loses volume due to the attenuation, then the audio signal may be enhanced by increasing levels of harmless audio content. That is, the audio processing may result in a decrease of energy in distortion-producing frequency bands and/or an increase of energy in distortion-masking frequency bands. Other examples of audio signal modification may be based on a determination of a critical sub-band (CSB) with a highest power level. For example, if a sum of the powers above the maximum sub-band is below a threshold, then some specific bands may be attenuated by an attenuation factor and other bands amplified by amplification factor. As another example, if a sum of the powers above the maximum sub-band is above a threshold, then some specific bands may be attenuated and other bands may be amplified.

The modified audio signal produced according to the signal processing described herein may be output to a speaker for reproduction. For example, a music file may be processed as an audio signal to obtain a modified audio signal that is played back through a speaker of a mobile phone for a user. As another example, a streaming video may include sounds that are processed as an audio signal to obtain a modified audio signal that is played back through a speaker of a mobile phone for a user. The audio processing may be performed by an integrated circuit, such as an audio controller of a smart phone. The audio controller may be a separate component in the smart phone or the audio controller may be integrated with other components, such as with a processor in a system on chip (SoC), in the smart phone.

Electronic devices incorporating the audio processing described above may benefit from improved audio quality played back through a speaker. For example, a mobile phone user may experience higher quality playback by reducing distortions introduced by the microspeaker. Attenuation may be applied to this audio content to reduce distortion introduced by the microspeaker.

Integrated circuits for performing the audio processing may include an analog-to-digital converter (ADC). The ADC may be used to convert an analog signal, such as an audio signal, to a digital representation of the analog signal. Additionally or alternatively, the integrated circuit may include a digital-to-analog converter (DAC). The DAC may receive an audio signal for playback, such as audio received from a digital music file or audio streamed over a wireless network. In some embodiments, the audio processing may be performed on the digital signal prior to input to the DAC, and the DAC converts the modified audio signal to an analog signal for amplification to drive a speaker. In some embodiments, the audio processing may be performed on an analog signal output from the DAC. The digital audio is output to the DAC for conversion to an analog signal, which is processed in the analog domain, and then the modified analog audio signal is amplified and used to drive a speaker. Integrated circuits with the audio processing functionality described herein may be used in electronic devices with audio outputs, such as music players, CD players, DVD players, Blu-ray players, headphones, portable speakers, headsets, mobile phones, tablet computers, personal computers, set-top boxes, digital video recorder (DVR) boxes, home theatre receivers, infotainment systems, automobile audio systems, and the like.

The foregoing has outlined rather broadly certain features and technical advantages of embodiments of the present invention in order that the detailed description that follows may be better understood. Additional features and advantages will be described hereinafter that form the subject of the claims of the invention. It should be appreciated by those having ordinary skill in the art that the conception and specific embodiment disclosed may be readily utilized as a basis for modifying or designing other structures for carrying out the same or similar purposes. It should also be realized by those having ordinary skill in the art that such equivalent constructions do not depart from the spirit and scope of the invention as set forth in the appended claims. Additional features will be better understood from the following description when considered in connection with the accompanying figures. It is to be expressly understood, however, that each of the figures is provided for the purpose of illustration and description only and is not intended to limit the present invention.

### BRIEF DESCRIPTION OF THE DRAWINGS

For a more complete understanding of the disclosed system and methods, reference is now made to the following descriptions taken in conjunction with the accompanying drawings.

FIG. 1 is a graph illustrating onset of sounds in an audio signal according to some embodiments of the disclosure.

FIG. 2 is a flow chart illustrating an example method for processing audio signals to reduce perceived audio distortion in a loudspeaker in response to an input audio signal according to some embodiments of the disclosure.

FIG. 3 is a flow chart illustrating an example method for detecting and compensating for onset in an input audio signal according to some embodiments of the disclosure.

FIG. 4 is a block diagram illustrating an integrated circuit for detecting and compensating for onset in an input audio signal according to some embodiments of the disclosure.

FIG. 5 is a flow chart illustrating another example method for detecting and compensating for onset in an input audio signal according to some embodiments of the disclosure.

FIG. 6 is a graph illustrating an input signal with critical sub-band power levels for the signal with sum of powers in a sub-band range being less than a power threshold according to one embodiment of the disclosure.

FIG. 7 is a graph illustrating an input signal with critical sub-band power levels for the signal with sum of powers in a sub-band range being greater than a power threshold according to one embodiment of the disclosure.

FIG. 8 is an illustration showing an example personal media device for audio playback including an audio controller that is configured to reduce distortion in reproduced audio according to one embodiment of the disclosure.

### DETAILED DESCRIPTION

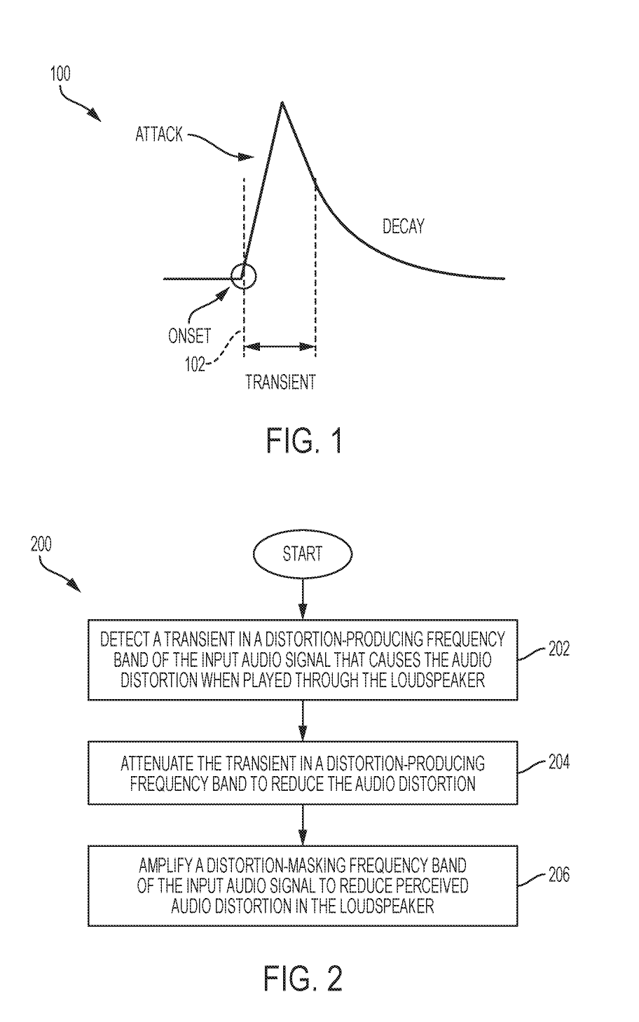

Sounds, including piano or non-piano sounds, consist of many discrete events with each discrete event having several phases. The beginning of a discrete event is an onset. FIG. 1 is a graph illustrating onset of sounds in an audio signal according to some embodiments of the disclosure. A discrete event 100 in an audio signal begins at time 102 with the beginning of an attack phase corresponding to a sharp increase in amplitude envelope. After the attack phase, the event is in a transient phase during which the signal evolves in an unpredictable manner. After the transient, the signal decays until another discrete event. Onset detection refers to the detection of the beginning of discrete events in acoustic signals, such as time 102. Perception of an onset by a listener is caused by a noticeable change in the intensity, pitch, or timbre of the sound. To detect onset, circuitry according to embodiments described herein can operate to distinguish rapid changes from gradual changes and modulations that occur during the ringing of a sound.

Processing may be performed to modify the audio signal when an onset is detected. When an onset is detected, compensation may be applied to reduce the perceptibility of the onset and thus improve audio quality for the listener. Without compensation, the audio signal may rapidly change during transient periods that drives a speaker to distort the audio. The audio distortion may be worse in small speakers, such as microspeakers incorporated into smart phones. Compensation may be adjusted during the attack or transient portions of a discrete event to reduce perception of the onset. Compensation applied during the attack or transient portions may have little or no effect on a loudness or bass content of the modified audio signal. Compensation may also be applied during decay portions of an event, but at different levels than compensation during the attack or transient portion. In some embodiments, compensation may be applied iteratively on frames of an audio signal until a desired metric for the audio signal is obtained.

One example method for applying compensation during a transient phase is described with reference to FIG. 2. FIG. 2 is a flow chart illustrating an example method for processing audio signals to reduce perceived audio distortion in a loudspeaker in response to an input audio signal according to some embodiments of the disclosure. A method 200 begins at block 202 with detecting a transient in a distortion-producing frequency band of the input audio signal that causes audio distortion when played through the loudspeaker. For example, block 202 may include detecting a change in the loudness volume exceeding a threshold level and/or whether the change is accompanied by an energy level of distortion-masking frequency bands below a threshold level. Then, at block 204, the transient is attenuated in the distortion-producing frequency band to reduce the audio distortion introduced by a speaker. At block 206, a portion of a distortion-masking frequency band is amplified to reduce perception of audio distortion caused by the speaker and/or recover sound pressure level (SPL) of the original audio signal. The distortion-masking frequency band may be higher in frequency than the distortion-producing frequency band. In some embodiments, the attenuation of block 204 may be performed without the amplification of block 206. In some embodiments, the amplification of block 206 may be performed without the attenuation of block 204. In some embodiments, attenuation and/or amplification may be selected for modifying the audio signal based on characteristics of the audio signal.

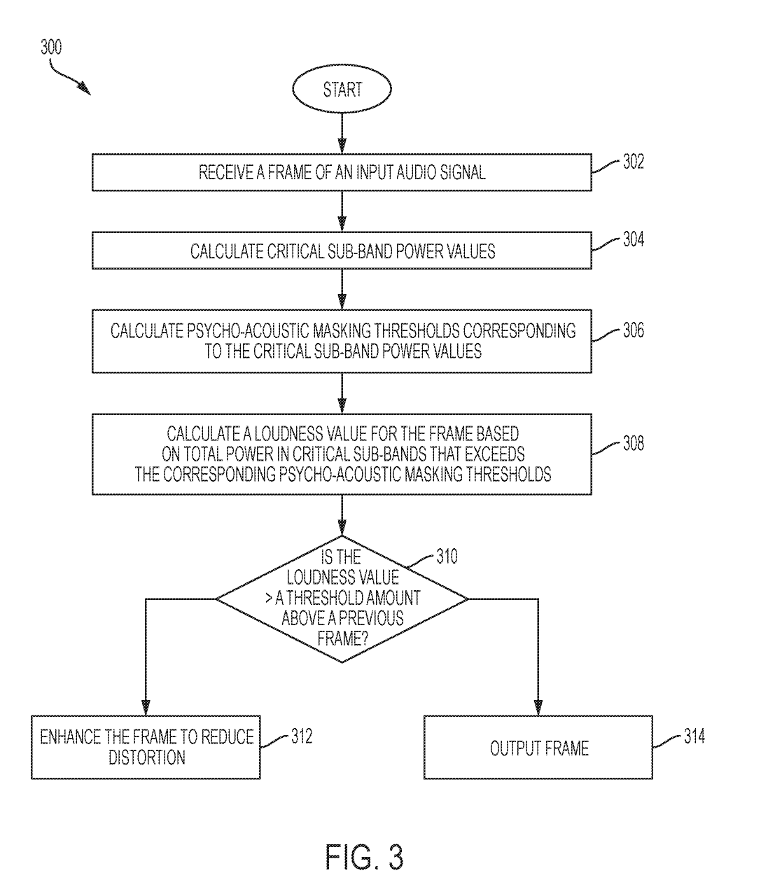

One example for detection of a transient in an event, such as performed at block 202, may be based on critical sub-band powers (CSBs). An example method using CSBs is described with reference to FIG. 3. FIG. 3 is a flow chart illustrating an example method for detecting and compensating for onset in an input audio signal according to some embodiments of the disclosure. A method 300 begins at block 302 with receiving a frame of an input audio signal. Characteristics of that frame are calculated, including sub-band power values and masking thresholds. At block 304, critical sub-band power values may be calculated for each critical sub-band. The critical sub-bands may be different frequency ranges within the audio signal, and each sub-band does not necessarily have an equal frequency distribution. At block 306, psycho-acoustic masking thresholds are calculated that correspond to the critical sub-band power values. The masking thresholds provide a value that corresponds to a threshold at which sounds in the critical sub-band are less perceptible. Psycho-acoustic masking thresholds are one type of masking threshold that may be used in audio processing. At block 308, a loudness value is computed for the received frame. The loudness value is a value that reflects an amount of energy in a signal that exceeds perceptible levels. One example calculation for a loudness value may involve summing across some or all critical sub-bands an amount that each individual sub-band power value exceeds a corresponding masking threshold. This is a total power in the critical sub-bands that exceeds the corresponding psycho-acoustic masking thresholds.

The received frame may be modified based on the determined characteristics, such as characteristics calculated at blocks 304, 306, and 308. For example, the loudness value of block 308 may be compared to a threshold at block 310. The threshold may be a loudness value of a previous frame or an average loudness value of several previous frames. Modification of the current audio frame may be turned on or off and/or adjusted based on the characteristic. The current frame may be modified at block 312 if the instantaneous loudness value of the current frame is greater than a threshold amount above a stored loudness value of a previous frame. The current frame may be output with little or no modification at block 314 if the instantaneous loudness value of the current frame is less than a threshold amount above the stored loudness value of a previous frame.

The enhancement of the audio signal at block 312 may include modifications that reduce distortion when the audio is reproduced by a speaker. Distortion-producing frequency bands may be attenuated to reduce the likelihood that the frame will drive the speaker to distort the sound, such as by exceeding a safe excursion limit. Enhancement of block 312 may additionally or alternatively include amplification of distortion-masking frequency bands. When distortion-masking frequency bands are increased in amplitude, the additional energy may cover distortion produced from the distortion-producing frequency bands. This amplification may reduce a listener's perception of the speaker distortion caused by the distortion-producing frequency bands. Others processes for enhancing the sound of an audio signal are described herein.

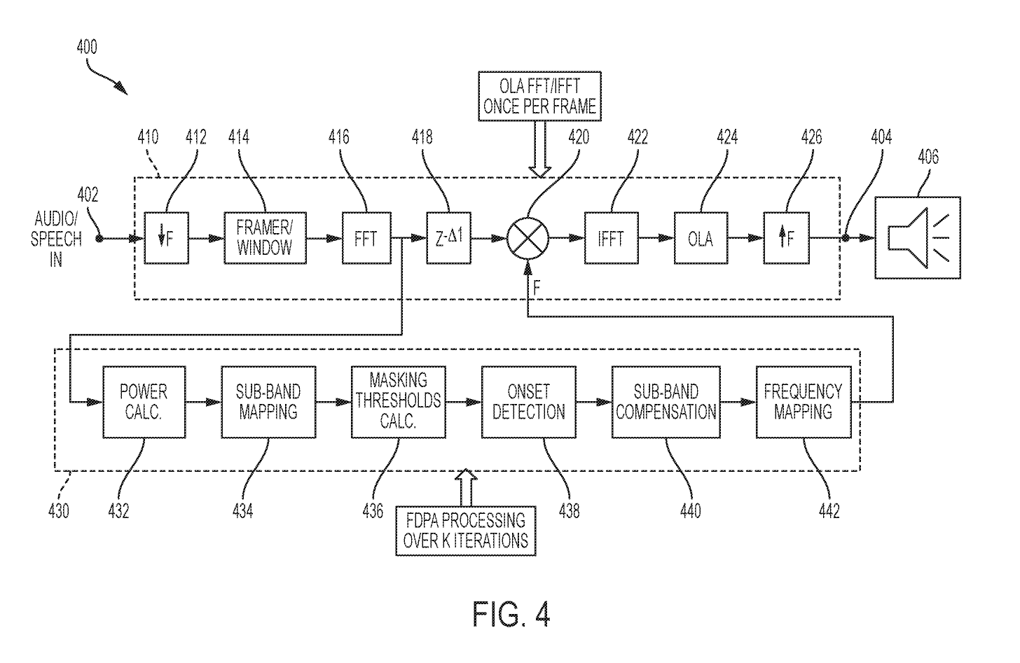

A block diagram for an integrated circuit for implementing one embodiment of portions or all of the methods described in FIG. 2 and FIG. 3 is shown in FIG. 4. FIG. 4 is a block diagram illustrating an integrated circuit for detecting and compensating for onset in an input audio signal according to some embodiments of the disclosure. A person of ordinary skill in the art can implement the block diagram of FIG. 4 in an integrated circuit, such as by programming a digital signal processor (DSP) or a central processing unit (CPU) or designing an application-specific integrated circuit (ASIC), to perform the functions described with reference to FIG. 4. An integrated circuit (IC) 400 receives an input audio signal at node 402 and processes the audio signal to generate an output at output node 404 for a loudspeaker 406. The audio signal may be passed through downconverter 412, framer 414, and Fast Fourier Transform (FFT) block 416 to obtain a frequency-domain representation of a single frame of the audio signal. The frequency information may be processed in blocks 430.

Blocks 430 may be executed to compensate the audio signal for onsets that may cause loudspeaker distortion. Blocks 430 may be executed once on each audio frame, a predetermined multiple number of times on each audio frame, and/or iterated through multiple times on each audio frame until a predetermined criteria is met. Processing blocks 430 may include a power calculation block 432, a sub-band mapping block 434, a masking threshold calculation block 436, an onset detection block 438, a sub-band compensation block 440, and a frequency mapping block 442. The blocks 430 may perform steps for accomplishing the tasks described with reference to FIG. 2. For example, the step of detecting a transient at block 202 may be performed in steps by blocks 432, 434, 436, and 438 and the steps of attenuating and amplifying at blocks 204 and 206 may be performed by block 440 to reduce audio distortion. Referring to the embodiment of FIG. 3, the framing of the input audio signal at block 302 may be performed by framer 414, the calculations of blocks 304 and 306 performed by blocks 432 and 434, the calculation of block 306 performed by block 436, the calculation of blocks 308 and 310 performed by block 438, and the audio modification of block 312 performed by block 440.

After the audio is enhanced by blocks 430, the modified audio frame is processed for output to a loud speaker. The enhanced audio frames after compensation at block 440 may have optimized sub-band coefficients that are reverse mapped at block 442 into frequency-domain coefficients and applied, at block 420, to the frequency-domain original frame passed from the FFT block 416 through filter 418. That result is inverse transformed at block 422 to obtain a time-domain signal. The time-domain signal is processed in Overlap and Add (OLA) block 424 to de-frame and then upconverted in upconverter 426. The modified audio frames are output to output node 404, which may be coupled to additional audio circuitry, such as a modulator, driver, and/or amplifier to drive loudspeaker 406. One example of a loudspeaker 406 is a microspeaker with a resonant frequency between approximately 300 Hertz and approximately 1500 Hertz. The processing performed in blocks 430 reduces or eliminates audio distortion caused by characteristics of loudspeaker 406 resulting from the onsets.

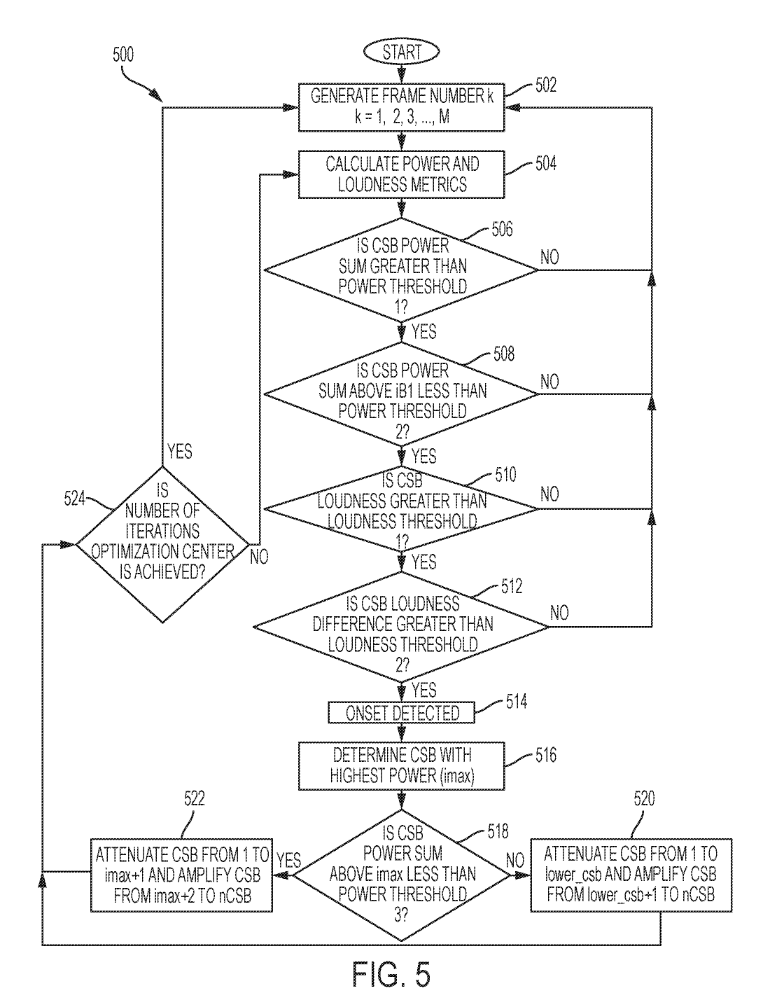

A detailed embodiment of processing audio frames from an input signal is described with reference to FIG. 5. FIG. 5 is a flow chart illustrating another example method for detecting and compensating for onset in an input audio signal according to some embodiments of the disclosure. However, FIG. 5 is only one example method and other methods for processing the audio signal may be used for enhancing the audio to reduce distortion caused by onsets. A method 500 begins at block 502 with receiving an input signal and generating an audio frame k in a series of audio frames. At block 504, power and loudness metrics are calculated for the audio frame. The audio frame may be subjected to one or more tests to determine if the audio frame may be subject to audio distortion and thus should be modified.

Preliminary testing of the audio frame may be performed at blocks 506, 508, 510, and 512. At block 506, it is determined whether the critical sub-band (CSB) power sum is greater than a first power threshold. If not, the method 500 returns to block 502 to process the next audio frame. If so, the method 500 continues to block 508 to determine if the CSB power sum above a particular band iB1 is less than a second power threshold, where iB1 is a predetermined value to separate a low set of frequencies from a high set of frequencies. An example band designated as iB1 may be a band containing the 2.5 kHz frequency. If not at block 506, the method 500 returns to block 502 to process the next audio frame. If so, the method 500 continues to block 510 to determine if the loudness value for the audio frame is greater than a first loudness threshold. If not, the method 500 returns to block 502 to process the next audio frame. If so, the method 500 continues to block 512 to determine if the a CSB loudness difference is greater than a second loudness threshold. If not, the method 500 returns to block 502 to process the next audio frame. If so, the audio frame is determined to be further analyzed for possible onset detection and modification.

Onset detection and audio enhancement are performed after the tests of blocks 506, 508, 510, and 512 are passed. At block 514, onset may be detected, after which a critical sub-band (CSB) with a highest power level (imax) is identified at block 516. The CSB determined at block 516 may be used as a processing point for how to modify the audio frame to reduce distortion. At block 518, it is determined whether a CSB power sum of CSBs higher than CSB with the highest power level exceeds a third power threshold. If not, the method 500 continues to block 520 to attenuate CSBs from 1 to a lower_csb value and amplify CSBs above the lower_csb value from lower_csb+1 to nCSB, where nCSB is the highest critical sub-band. The lower_csb value may be selected such that the CSB at lower_csb is higher than the CSB with the highest power level and such that the CSBs from 1 to lower_csb cover the frequency range of audio that can create audio distortion in the loudspeaker. For example, with a microspeaker, the lower_csb value may be a CSB corresponding to a frequency of approximately 1.7 kHz. After modification at block 520, the method 500 continues to block 524 to determine if the audio frame should be processed again based on the number of iterations already performed and/or criteria for the audio frame. Criteria for determining whether additional processing should be performed may include power, loudness, SPL, and/or onset detection. If further processing of the audio frame is indicated, then the method 500 continues to block 504 to again process the same data frame. If no further processing of the audio frame is indicated, then the method 500 returns to block 502 to generate a new audio frame from the audio signal. Returning to block 518, if the CSB power sum above imax is less than the third power threshold, then the method 500 continues to block 522. At block 522, the audio frame is modified by attenuating CSBs from 1 through one above the highest power level CSB and amplifying CSBs from two above the highest power level CSB to the highest CSB nCSB. After modifying the audio frame at block 522, the method continues to block 524 to determine if more processing of the audio frame is indicated. If not, additional frames are processed beginning at block 502. In some embodiments, the method 500 may include attenuating additional frames of the input audio signal after an initial frame having the detected transient until a loudness threshold is achieved.

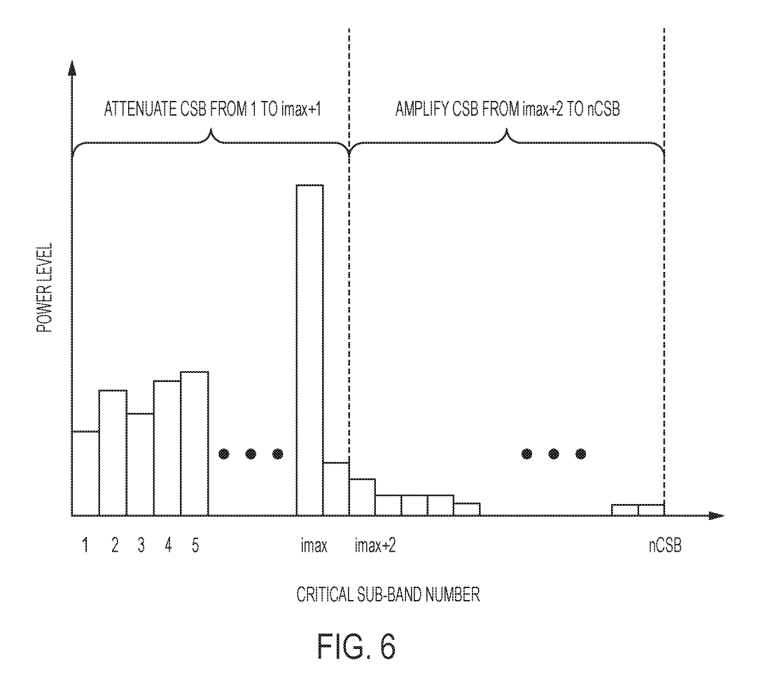

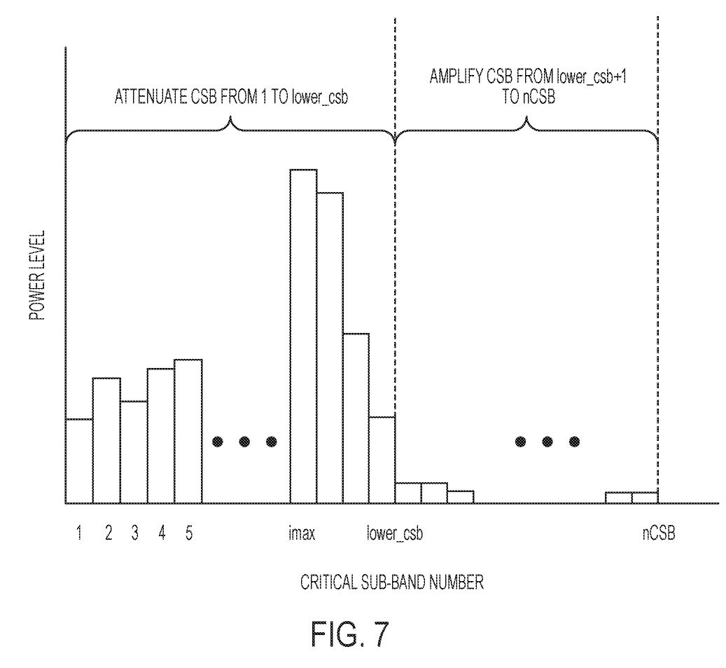

Example power levels for audio frames that will be modified according to block 520 or block 522 are illustrated in FIG. 6 and FIG. 7. FIG. 6 is a graph illustrating an input signal with critical sub-band power levels for the signal with sum of powers in a sub-band range being less than a power threshold according to one embodiment of the disclosure. An audio frame with the CSB power levels shown in FIG. 6 will be determined at block 518 to be processed as described in block 522. FIG. 7 is a graph illustrating an input signal with critical sub-band power levels for the signal with sum of powers in a sub-band range being greater than a power threshold according to one embodiment of the disclosure. An audio frame with the CSB power levels shown in FIG. 7 will be determined at block 518 to be processed as described in block 520.

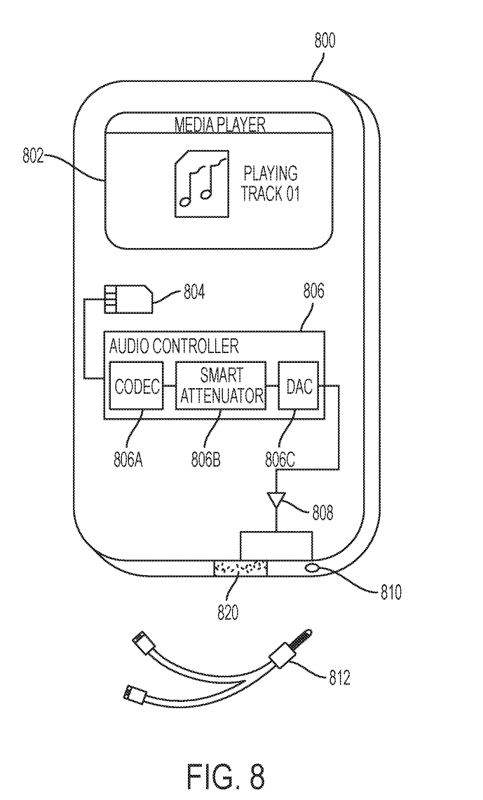

One advantageous embodiment for an audio processor described herein is a personal media device for playing back music, high-fidelity music, and/or speech from telephone calls. FIG. 8 is an illustration showing an example personal media device for audio playback including an audio controller that is configured to reduce distortion in reproduced audio according to one embodiment of the disclosure. A personal media device 800 may include a display 802 for allowing a user to select from music files for playback, which may include both high-fidelity music files and normal music files. When music files are selected by a user, audio files may be retrieved from memory 804 by an application processor (not shown) and provided to an audio controller 806. The audio controller 806 may include a coder/decoder (CODEC) 806A and audio processing circuitry including smart attenuator 806B and DAC 806C. The smart attenuator 806B may implement audio processing to modify an input audio signal, such as according to the embodiments of FIG. 2, FIG. 3, FIG. 4, or FIG. 5. The digital audio (e.g., music or speech) may be converted to analog signals by the audio controller 806, and those analog signals amplified by an amplifier 808. Although the smart attenuator 806B is shown operating on the digital signal prior to conversion to an analog signal, the smart attenuator in other embodiments may operate on the analog signal. The amplifier 808 may be coupled to an audio output 810, such as a headphone jack, for driving a transducer, such as headphones 812. The amplifier 808 may also be coupled to an internal speaker 820 of the device 800. When a headphone is connected at audio output 810, the smart attenuator 806B may be disabled because the headphones 812 do not introduce the same distortion as speaker 820. In some embodiments, the smart attenuator 806B is provided an indication of when the headphones 812 are connected at audio output 810 along with an indication of the type of headphones such that the smart attenuator may modify processing to reduce distortions that are specific to the headphones 812. Although the data received at the audio controller 806 is described as received from memory 804, the audio data may also be received from other sources, such as a USB connection, a device connected through Wi-Fi to the personal media device 800, a cellular radio, an Internet-based server, another wireless radio, and/or another wired connection.

Some sounds may be more likely to cause audio distortion. Pianos have a strong attack audio event when keys are pressed to cause the hammers to strike the strings. The strong attack of a piano at frequencies near the resonant frequency of the loudspeaker can cause audio distortion. The audio distortion may be particularly noticeable to a listener in solo piano music, where there are no other sounds to cover the audio distortion. Modification of audio frames of music with piano or piano-like sounds reduces the audio distortion and improves the quality of audio reproduction as perceived by the listener. The modification may be particularly advantageous on small speakers, such as microspeakers in mobile devices.

The operations described above as performed by a controller may be performed by any circuit configured to perform the described operations. Such a circuit may be an integrated circuit (IC) constructed on a semiconductor substrate and include logic circuitry, such as transistors configured as logic gates, and memory circuitry, such as transistors and capacitors configured as dynamic random access memory (DRAM), electronically programmable read-only memory (EPROM), or other memory devices. The logic circuitry may be configured through hard-wire connections or through programming by instructions contained in firmware. Further, the logic circuitry may be configured as a general-purpose processor (e.g., CPU or DSP) capable of executing instructions contained in software. The firmware and/or software may include instructions that cause the processing of signals described herein to be performed. The circuitry or software may be organized as blocks that are configured to perform specific functions. Alternatively, some circuitry or software may be organized as shared blocks that can perform several of the described operations. In some embodiments, the integrated circuit (IC) that is the controller may include other functionality. For example, the controller IC may include an audio coder/decoder (CODEC) along with circuitry for performing the functions described herein. Such an IC is one example of an audio controller. Other audio functionality may be additionally or alternatively integrated with the IC circuitry described herein to form an audio controller.

If implemented in firmware and/or software, functions described above may be stored as one or more instructions or code on a computer-readable medium. Examples include non-transitory computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise random access memory (RAM), read-only memory (ROM), electrically-erasable programmable read-only memory (EEPROM), compact disc read-only memory (CD-ROM) or other optical disk storage, magnetic disk storage or other magnetic storage devices, or any other medium that can be used to store desired program code in the form of instructions or data structures and that can be accessed by a computer. Disk and disc includes compact discs (CD), laser discs, optical discs, digital versatile discs (DVD), floppy disks and Blu-ray discs. Generally, disks reproduce data magnetically, and discs reproduce data optically. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The described methods are generally set forth in a logical flow of steps. As such, the described order and labeled steps of representative figures are indicative of aspects of the disclosed method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagram, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Although the present disclosure and certain representative advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. For example, where general purpose processors are described as implementing certain processing steps, the general purpose processor may be a digital signal processors (DSPs), a graphics processing units (GPUs), a central processing units (CPUs), or other configurable logic circuitry. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding embodiments described herein may be utilized. Accordingly, the appended claims are intended to include within their scope such processes, machines, manufacture, compositions of matter, means, methods, or steps.

1. A method for reducing perceived audio distortion in a loudspeaker in response to an input audio signal, the method comprising:
detecting a transient in a distortion-producing frequency band of the input audio signal that causes the audio distortion when played through the loudspeaker; and
attenuating the transient in a distortion-producing frequency band to reduce the audio distortion.

2. The method of claim 1, wherein the step of detecting a transient in a distortion-producing frequency band comprises determining a critical sub-band power for a frame of the input audio signal.

3. The method of claim 2, wherein the step of detecting a transient in a distortion-producing frequency band comprises determining whether the critical sub-band power exceeds a psycho-acoustic masking threshold.

4. The method of claim 3, wherein the step of detecting a transient in a distortion-producing frequency band comprises determining whether a loudness value calculated as a sum of powers in a plurality of critical sub-band powers exceeding respective psycho-acoustic masking thresholds exceeds a threshold level.

5. The method of claim 4, wherein the step of detecting a transient in a distortion-producing frequency band comprises detecting a change in the loudness volume exceeding a threshold level.

6. The method of claim 5, wherein the step of detecting a transient in a distortion-producing frequency band comprises detecting the change in the loudness volume is accompanied by an energy level of the distortion-masking frequency bands below a threshold level.

7. The method of claim 1, further comprising amplifying a distortion-masking frequency band of the input audio signal to reduce perceived audio distortion in the loudspeaker.

8. The method of claim 1, wherein the steps of detecting a transient and attenuating the transient are performed on a frame-by-frame basis for the input audio signal, and wherein the method further comprises iteratively processing a frame of the input audio signal to attenuate the transient.

9. The method of claim 1, wherein the step of detecting a transient comprises detecting a transient and attenuating the transient in a first frame of the input audio signal, and wherein the method further comprises attenuating additional frames of the input audio signal until a loudness threshold is achieved.

10. The method of claim 1, wherein the loudspeaker comprises a microspeaker with a resonant frequency in the 300 Hz to 1500 Hz range.

11. The method of claim 1, wherein a frequency range of the distortion-masking frequency band is higher in frequency than a frequency range of the distortion-producing frequency band.

12. An apparatus, comprising:
an audio controller configured to perform steps for reducing perceived audio distortion in a loudspeaker in response to an input audio signal comprising:
detecting a transient in a distortion-producing frequency band of the input audio signal that causes the audio distortion when played through the loudspeaker; and
attenuating the transient in a distortion-producing frequency band to reduce the audio distortion.

13. The apparatus of claim 12, wherein the audio controller is configured to detect a transient in a distortion-producing frequency band by determining a critical sub-band power for a frame of the input audio signal.

14. The apparatus of claim 13, wherein the audio controller is configured to detect a transient in a distortion-producing frequency band by determining whether the critical sub-band power exceeds a psycho-acoustic masking threshold.

15. The apparatus of claim 14, wherein the audio controller is configured to detect a transient in a distortion-producing frequency band by determining whether a loudness value calculated as a sum of powers in a plurality of critical sub-band powers exceeding respective psycho-acoustic masking thresholds exceeds a threshold level.

16. The apparatus of claim 15, wherein the audio controller is configured to detect a transient in a distortion-producing frequency band by detecting a change in the loudness volume exceeding a threshold level.

17. The apparatus of claim 16, wherein the audio controller is configured to detect a transient in a distortion-producing frequency band by detecting the change in the loudness volume is accompanied by an energy level of the distortion-masking frequency bands below a threshold level.

18. The apparatus of claim 12, wherein the audio controller is further configured to amplify a distortion-masking frequency band of the input audio signal.

19. The apparatus of claim 12, wherein the audio controller is configured to detect a transient and attenuate the transient on a frame-by-frame basis for the input audio signal, and wherein the audio controller is further configured to iteratively process a frame of the input audio signal to attenuate the transient.

20. The apparatus of claim 12, wherein the audio controller is further configured to attenuate additional frames of the input audio signal after an initial frame having the detected transient until a loudness threshold is achieved.

21. A mobile device, comprising:
a microspeaker having a resonant frequency between approximately 300 Hz and approximately 1500 Hz;
an audio controller configured to receive an input audio signal and to processing the input audio signal to generate a modified audio signal for output to the micro speaker,
wherein the audio controller is configured to generate the modified audio signal by performing steps comprising:
detecting a transient in a distortion-producing frequency band of the input audio signal that causes the audio distortion when played through the loudspeaker;
attenuating the transient in a distortion-producing frequency band to reduce the audio distortion; and
amplifying a distortion-masking frequency band of the input audio signal.

22. The apparatus of claim 21, wherein the audio controller is configured to generate frames from the input audio signal and generate the modified audio signal by processing the frames in a frequency domain using a psycho-acoustic model.

23. The apparatus of claim 21, wherein the audio controller is configured to detect a transient in a distortion-producing frequency band by determining whether a loudness value exceeds a threshold level, wherein the loudness value is calculated as a sum of amounts that power levels in a plurality of critical sub-band powers exceed their respective psycho-acoustic masking thresholds.
